(19) United States
(12) Patent Application Publication
(10) Pub. No.: US 2024/0224760 A1
(43) Pub. Date: Jul. 4, 2024

(54) FOLDABLE DISPLAY DEVICE

(71) Applicant: LG Display Co., Ltd., Seoul (KR)

(72) Inventors: Suk Choi, Paju-si (KR); Kyungmin Yeo, Paju-si (KR)

(73) Assignee: LG Display Co., Ltd., Seoul (KR)

(21) Appl. No.: 18/371,743

(22) Filed: Sep. 22, 2023

(30) Foreign Application Priority Data
Dec. 28, 2022 (KR) 10-2022-0187157

(51) Int. Cl. H10K 59/80; G02B 1/14; G02B 1/18; H10K 77/10

(52) U.S. Cl. CPC H10K 59/8791; G02B 1/14; G02B 1/18; H10K 59/8722; H10K 77/111; H10K 2102/311

(57) ABSTRACT

Provided is a foldable display device. In one aspect, a foldable display device includes a display panel including a folding area to be folded with respect to a folding axis and a non-folding area; a polarization film on the display panel; an adhesive member on the polarization film; and a retardation film on the adhesive member, wherein each of an in-plane retardation value and a thickness retardation value of the retardation film is 10 nm or less.

### CROSS-REFERENCE TO RELATED APPLICATIONS

This application claims priority to Korean Patent Application No. 10-2022-0187157 filed on Dec. 28, 2022, in the Korean Intellectual Property Office, the entire disclosure of which is incorporated herein by reference.

### BACKGROUND

### Field of the Disclosure

The present disclosure relates to a foldable display device, and more particularly, to a foldable display device which may improve high dynamic range (HDR) characteristics.

### Description of the Background

In today's world, the use of consumer electronic devices including various types of display devices is on the rise. This rise has led to the development of many different types and forms of display devices that are thin, light, and have low power consumption are being developed. Examples of display devices may include a liquid crystal display (LCD) device, a plasma display panel (PDP) device, a field emission display (FED) device, an organic light-emitting display (OLED) device, etc.

Among these display devices, OLED devices do not require a separate light source. Therefore, OLED devices may be manufactured as lightweight and thin devices with advantageous processing capabilities driven with low voltage leading to less power consumption.

In general, OLED devices include a polarization film and a retardation film on a display panel to suppress degradation in visibility and contrast ratio caused by light incident into such display devices from the outside.

Recently, the shapes and sizes of display devices have been gradually diversified. Particularly, interests in foldable display devices capable of maintaining display performance even when the display devices are folded or rolled have continued to increase. In accordance with the interests, research and development on panels, fixtures, and cover windows having a specific radius of curvature are being conducted actively.

### SUMMARY

The present disclosure is directed to a foldable display device which may improve HDR properties and viewing angle properties.

One or more example embodiments of the present disclosure provide a foldable display device which can maintain a high display quality and has excellent folding reliability. Thus, it may be implemented as various flexible display devices such as a foldable display device, a rollable display device, etc.

The present disclosure is not limited to example embodiments described above and/or those which will be described hereinafter but can be realized in a variety of different forms clearly understood by those skilled in the art from the following descriptions.

In one aspect, a foldable display device includes a display panel including a folding area to be folded with respect to a folding axis and a non-folding area: a polarization film on the display panel: an adhesive member on the polarization film: and a retardation film on the adhesive member, wherein each of an in-plane retardation value and a thickness retardation value of the retardation film is 10 nm or less.

In another aspect, the thickness retardation value of the retardation film is equal to or smaller than the in-plane retardation value.

In another aspect, the polarization film has a greater refractive index than the adhesive member, and the adhesive member has a greater refractive index than the retardation film.

In another aspect, the foldable display device further includes an adhesive layer bonding the polarization film to the display panel.

In another aspect, the foldable display device further includes a hard coating layer on the retardation film having a contact angle to provide anti-fingerprint function.

In another aspect, the foldable display device further includes a hard coating layer on the retardation film, and an anti-fingerprint layer on the hard coating layer.

In another aspect, the polarization film includes a polarizer: and an upper protective film on the polarizer. Each of an in-plane retardation value and a thickness retardation value of the upper protective film is 10 nm or less, and the thickness retardation value of the upper protective film is equal to or smaller than the in-plane retardation value.

In another aspect, the polarization film further includes a second retardation film under the polarizer, and a C plate under the second retardation film.

In another aspect, the polarization film includes an upper protective film having a thickness retardation value that is equal to or smaller than the in-plane retardation value.

In another aspect, the foldable display device further includes a thin cover glass between the polarization film and the adhesive member.

In another aspect, the thin cover glass has a refractive index of 1.51 to 1.53.

In another aspect, an in-plane retardation value of the thin cover glass is greater than a thickness retardation value of the thin cover glass.

In another aspect, the adhesive member includes a first adhesive member on the polarization film: and a second adhesive member on the first adhesive member. The second adhesive member has a greater storage modulus than the first adhesive member.

In another aspect, the second adhesive member has a greater refractive index than the first adhesive member.

In another aspect, the foldable display device further includes a chemically strengthened glass on the display panel.

In one aspect, a display device includes a foldable display panel, a polarization film on the foldable display panel, an adhesive member on the polarization film, and a retardation film on the adhesive member having an in-plane retardation value and a thickness retardation value, wherein the thickness retardation value is equal to or less than the in-plane retardation value.

In another aspect, the polarization film has a greater refractive index than the adhesive member, and the adhesive member has a greater refractive index than the retardation film.

In another aspect, the polarization film includes an upper protective film having a thickness retardation value that is equal to or smaller than the in-plane retardation value.

In another aspect, the adhesive member includes a first adhesive member on the polarization film: and a second adhesive member on the first adhesive member. The second adhesive member has a greater storage modulus than the first adhesive member.

In another aspect, the polarization film has a greater refractive index than the adhesive member, and the adhesive member has a greater refractive index than the retardation film.

According to the present disclosure, excellent display quality and folding reliability may be secured. Thus, it is possible to implement various flexible foldable display devices such as a foldable display device and a rollable display device.

According to the present disclosure, HDR properties and viewing angle properties may be improved. Thus, it is possible to provide a foldable display device having excellent display quality.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a foldable display device according to an exemplary aspect of the present disclosure:

FIG. 2 is a schematic cross-sectional view of the foldable display device according to an exemplary aspect of the present disclosure:

FIG. 3 is a cross-sectional view schematically illustrating a polarization film of a foldable display device according to an exemplary aspect of the present disclosure:

FIG. 4 is a schematic cross-sectional view of a foldable display device according to an exemplary aspect of the present disclosure: and

FIG. 5 is a schematic cross-sectional view of a foldable display device according to an exemplary aspect of the present disclosure.

### DETAILED DESCRIPTION

Various examples of the present disclosure are discussed in detail below. While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment: and, such references mean at least one of the embodiments.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various examples of the present disclosure may be partially or entirely adhered to or combined with each other and may be interlocked and operated in technically various ways, and the embodiments may be carried out independently of or in association with each other.

Hereinafter, a display device according to exemplary embodiments of the present disclosure will be described in detail with reference to accompanying drawings.

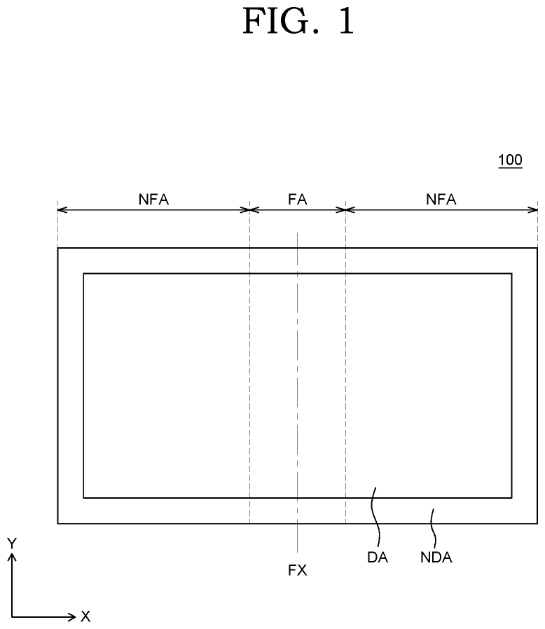

FIG. 1 is a schematic plan view of a foldable display device according to an exemplary aspect of the present disclosure.

Referring to FIG. 1, a foldable display device 100 according to an exemplary aspect of the present disclosure includes a display area DA and a non-display area NDA. The display area DA is an area where a plurality of pixels is disposed to substantially display an image. In the display area DA, a plurality of pixels including an emission area for displaying an image, a thin film transistor for driving the pixels, a capacitor, and the like may be disposed. Each pixel may include a plurality of sub-pixels SP. The sub-pixel SP is a minimum unit constituting the display area, and each sub-pixel SP may be configured to emit light of a specific wavelength band. For example, each of the sub-pixels SP may be configured to emit red light, green light, blue light, or white light. The non-display area NDA is disposed to enclose the display area DA. The non-display area NDA is an area where an image is not displayed and various lines and driving ICs for driving the pixels and the driving elements disposed in the display area DA are disposed. For example, various ICs such as a gate driver IC and a data driver IC, VSS lines, and the like may be disposed in the non-display area NDA.

The foldable display device 100 according to an exemplary aspect of the present specification includes a folding area FA and a non-folding area NFA. The folding area FA is an area which is folded when the foldable display device 100 is folded. The folding area FA maybe folded in accordance with a specific radius of curvature with respect to a folding axis FX. For example, the folding axis FX of the folding area FA may be formed in a Y-axis direction. Also, the non-folding area NFA may extend from the folding area FA in an X-axis direction perpendicular to the folding axis FX.

When the foldable display device 100 is folded and the folding area FA is folded with respect to the folding axis FX, the folding area FA may form a part of a circle or an oval. Here, a radius of curvature of the folding area FA may refer to a radius of a circle or an oval formed by the folding area FA. An upper surface of the foldable display device 100 may be a display surface configured to display an image and a lower surface of the foldable display device 100 may be an opposite rear surface relative to the display surface. In this case, the folding area FA may be folded by an out-folding method in which the display surface of the foldable display device 100 is folded to be exposed to the outside. Alternatively, the folding area FA may be folded by an in-folding method in which regions of the display surface of the foldable display device 100 face each other.

The non-folding area NFA is an area which is not folded when the foldable display device 100 is folded. For example, the non-folding area NFA maintains a flat state when the foldable display device 100 is folded. The non-folding area NFA may be located on both sides of the folding area FA. For example, the non-folding area NFA may be an area extending in the X-axis direction with respect to the folding axis FX.

The folding area FA may be disposed between the non-folding areas NFA. Also, when the foldable display device 100 is folded with respect to the folding axis FX, the non-folding areas NFA may overlap each other.

FIG. 1 illustrates that the foldable display device 100 includes one folding area FA and two non-folding areas NFA. However, the numbers and positions of folding areas FA and non-folding areas NFA is not limited to that shown in FIG. 1 and may be changed according known or to be developed device and/or associated design specifics.

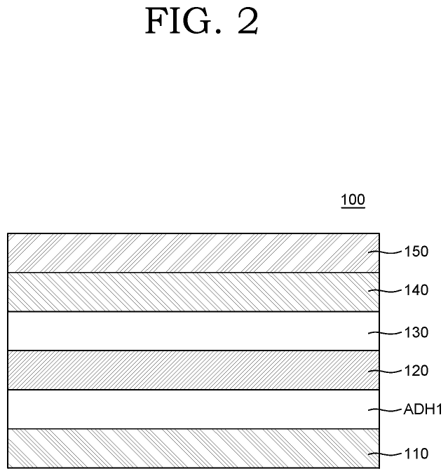

The foldable display device 100 according to an exemplary aspect of the present disclosure includes a display panel 110, a polarization film 120, an adhesive member 130, and a retardation film 140. The display panel 110, the polarization film 120, the adhesive member 130, and the retardation film 140 will be described in detail with reference to FIG. 2.

FIG. 2 is a schematic cross-sectional view of the foldable display device according to an exemplary aspect of the present disclosure.

Referring to FIG. 2, the display panel 110 may be a panel on which an image can be displayed, and may include a display element for displaying an image, a circuit unit for driving the display element, and the like. For example, when the foldable display device 100 is an organic light-emitting display device, the display element may include an organic light-emitting element. Hereinafter, for the convenience of description, it is assumed that the foldable display device 100 according to various exemplary embodiments of the present disclosure is a display device including an organic light-emitting element. However, the present disclosure is not limited thereto.

The circuit unit may include various thin film transistors, capacitors, lines, and driving ICs configured to drive the organic light-emitting element. For example, the circuit unit may include various components such as a driving thin film transistor, a switching thin film transistor, a storage capacitor, a gate line, a data line, a gate driver IC, and a data driver IC. However, the present disclosure is not limited thereto.

In the foldable display device 100, the display panel 110 includes a flexible substrate having a very small thickness to implement flexibility. The flexible substrate may be made of an insulating material having flexibility. For example, the flexible substrate may be an insulating plastic substrate made of one of polyimide, polyethersulfone, polyethylene terephthalate, and polycarbonate. However, the present disclosure is not limited thereto. The foldable display device 100 may be made of any material having flexibility that enables the foldable display device 100 to be repeatedly folded without significant damage, as well as plastic. While the flexible substrate has excellent flexibility, it is relatively thinner and less rigid than a glass substrate. Thus, when various elements are disposed on the flexible substrate, sagging of the substrate may occur. Accordingly, if necessary, a support member such as a back plate may be further disposed under the flexible substrate.

The back plate supports the flexible substrate to suppress sagging of the flexible substrate, and protects components disposed on the flexible substrate against external moisture, heat, impacts, and the like. The back plate may be made of a plastic material such as polymethylmethacrylate, polycarbonate, polyvinyl alcohol, acrylonitrile-butadiene-styrene, or polyethylene terephthalate. However, the present disclosure is not limited thereto. When the back plate is disposed under the flexible substrate, an adhesive layer may be disposed between the flexible substrate and the back plate to bond them together. The adhesive layer may be made of an optical clear adhesive, a pressure sensitive adhesive, and an optical clear resin, but is not limited thereto.

The polarization film 120 is disposed on the display panel 110. For example, the polarization film 120 may be bonded onto the display panel 110 by a first adhesive layer ADH1. The first adhesive layer ADH1 may be made of an optical clear adhesive for displays, such as a pressure sensitive adhesive, an optical clear adhesive, and an optical clear resin. However, if the polarization film 120 is made of a liquid coating agent, the first adhesive layer ADH1 may be omitted.

The polarization film 120 may selectively transmit light to reduce reflection of external light incident into the display panel 110. Specifically, the display panel 110 includes various metal layers applied to thin film transistors, lines, organic light-emitting elements, etc. Accordingly, external light incident into the display panel 110 may be reflected from a metal layer having high reflectivity. Thus, the visibility of the foldable display device 100 may be degraded due to the reflection of the external light. The polarization film 120 linearly polarizes external light in a predetermined direction. Therefore, it is possible to minimize the reflection of the external light and improve the visibility and contrast ratio of the foldable display device 100.

The adhesive member 130 is disposed on the polarization film 120. The adhesive member 130 bonds the retardation film 140 onto the polarization film 120. The adhesive member 130 is a transparent adhesive member, and may be made of an optical clear adhesive, a pressure sensitive adhesive, an optical clear resin, and the like, but is not limited thereto. For example, if the adhesive member 130 is made of the optical clear adhesive, an additive may be added to control the adhesiveness. For example, an additive which generates a thermal, UV, optical, or chemical reaction may be mixed into the adhesive member 130.

The adhesive member 130 may have a storage modulus of 10⁴ Pa to 10⁶ Pa. The storage modulus relates to folding properties. If the adhesive member 130 has a storage modulus in the above-described range, the folding properties and reliability are improved due to the storage modulus of the adhesive member 130. Also, the flexibility may be enhanced. Therefore, it is possible to easily implement flexible display devices such as a foldable display device and a rollable display device.

The retardation film 140 is disposed on the adhesive member 130. The retardation film 140 may be a film made of any one of polyethylene terephthalate, polyethersulfone, polycarbonate, polyimide, polypropylene, cyclo olefin polymer, cyclo olefin copolymer, and polymethylmethacrylate. Preferably, the retardation film 140 may be a polyethylene terephthalate film. The polyethylene terephthalate film is cheap and easy to obtain and its properties such as a phase difference may be easily controlled.

Each of an in-plane retardation value Rin and a thickness retardation value Rth of the retardation film 140 may be 10 nm or less (is between a positive non-zero value and a maximum of 10 nm). If each of the in-plane retardation value Rin and the thickness retardation value Rth of the retardation film 140 is greater than 10 nm, a blue color may be recognized or distorted depending on a viewing angle. Also, a difference in refractive index between a front viewing angle and another viewing angle may increase, which may be recognized as high refraction. Thus, viewing angle properties may be degraded. If each of the in-plane retardation value Rin and the thickness retardation value Rth of the retardation film 140 is 10 nm or less (is between a positive non-zero value and a maximum of 10 nm), other colors are not recognized nor distorted depending on a viewing angle. Also, a difference in refractive index between the front viewing angle and another viewing angle may decrease, which may be recognized as low refraction. Thus, the viewing angle properties may be improved. Preferably, each of the in-plane retardation value Rin and the thickness retardation value Rth of the retardation film 140) may between 1 nm to 3 nm.

In this case, the thickness retardation value Rth of the retardation film 140 may be equal to or smaller than the in-plane retardation value Rin. If the thickness retardation value Rth of the retardation film 140 is greater than the in-plane retardation value Rin, a color or transmittance may be changed depending on a viewing angle. Also, a refractive index may be changed, and, thus, the viewing angle properties may be degraded. If the thickness retardation value Rth of the retardation film 140 is equal to or smaller than the in-plane retardation value Rin, the color or transmittance is not affected by the viewing angle and thus is not changed. Also, the refractive index may not be changed, and, thus, the viewing angle properties may be improved.

A hard coating layer 150 may be disposed on the retardation film 140. The hard coating layer 150 is the outermost layer where an image is implemented, and may protect the foldable display device 100 against external foreign matters or scratches. Thus, the hard coating layer 150 may be made of a material suppressing contamination by surrounding environment and having high resistance to external impacts. For example, the hard coating layer 150 may be made of a urethane-based resin or an acryl-based resin, or may be made of silica particles or nanoparticles (Al₂O₃) to maintain a thickness and hardness, but is not limited thereto. For example, the hard coating layer 150 may have a hardness of 6H or more and a thickness of 10 μm. For example, the hard coating layer 150 may have a contact angle of 105 or more for an anti-fingerprint function. Instead of forming the hard coating layer 150 with a contact angle of 105 degrees or more, a separate anti-fingerprint layer may be disposed on the hard coating layer 150 for the anti-fingerprint function. Herein, a refractive index of the anti-fingerprint layer may be equal to that of the hard coating layer 150. The hard coating layer 150 may be formed by directly coating a hard coating composition. Alternatively, the hard coating layer 150 may be formed by bonding a hard coating film onto the retardation film 140 with an adhesive.

Meanwhile, to improve display quality, the polarization film 120 may have a greater refractive index than the adhesive member 130, and the adhesive member 130 may have a greater refractive index than the retardation film 140. For example, the polarization film 120 may have a refractive index of 1.38 to 1.58, and the adhesive member 130 may have a refractive index of 1.48 to 1.55. Also, the retardation film 140 may have a refractive index of 1.38 to 1.58. That is, the polarization film 120 has a greater refractive index than the adhesive member 130 and the adhesive member 130 has a greater refractive index than the retardation film 140. In this case, out-coupling is minimized, and, thus, micro-cavity effect is increased. Therefore, HDR properties may be improved.

In the foldable display device 100 according to an exemplary aspect of the present disclosure, the folding properties maybe improved when the viewing angle properties are improved. For example, if a window substrate is made of glass, the folding properties may be degraded. Thus, if the window substrate is made of colorless PI (CPI) or polyethylene terephthalate (PET) to improve the folding properties, the viewing angle properties may be degraded. Therefore, in the foldable display device 100 according to an exemplary aspect of the present disclosure, the retardation film 140 may be used instead of glass as the window substrate to improve the folding properties. In this case, each of the in-plane retardation value Rin and the thickness retardation value Rth of the retardation film 140 is set to 10 nm or less (is between a positive non-zero value and a maximum of 10 nm). Therefore, other colors are not recognized nor distorted depending on a viewing angle. Also, a difference in refractive index between the front viewing angle and another viewing angle decreases, which is recognized as low refraction. Thus, the viewing angle properties may be improved. Further, the thickness retardation value Rth of the retardation film 140 is equal to or smaller than the in-plane retardation value Rin. Thus, the color or transmittance is not affected by the viewing angle and thus is not changed. Furthermore, the refractive index is not changed, and, thus, the viewing angle properties may be improved.

In the foldable display device 100 according to an exemplary aspect of the present disclosure, the polarization film 120, the adhesive member 130, and the retardation film 140 are sequentially disposed. Also, the polarization film 120 has a greater refractive index than the adhesive member 130, and the adhesive member 130 has a greater refractive index than the retardation film 140. When the refractive indexes of the polarization film 120, the adhesive member 130, and the retardation film 140 are matched, the out-coupling is minimized. Thus, the micro-cavity effect is increased. Therefore, the HDR properties may be improved.

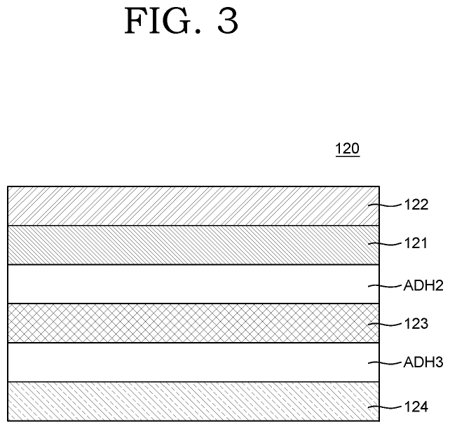

FIG. 3 is a cross-sectional view schematically illustrating a polarization film of a foldable display device according to an exemplary aspect of the present disclosure.

Referring to FIG. 3, the polarization film 120 may include a polarizer 121, an upper protective film 122, a /4 retardation film 123, and a positive C plate 124.

The polarizer 121 polarizes light in one direction. For example, the polarizer 121 may be selected from an iodine-based polarization film, a dye-based polarization film, a polyene-based polarization film, and the like. The iodine-based polarization film is oriented by polyvinyl alcohol (PVA) chains obtained by stretching and orienting iodine ion chains to have polarization properties. The dye-based polarization film is also oriented by PVA chains obtained by stretching and orienting a dichroic dye to have polarization properties. Meanwhile, the polyene-based polarization film produces polyene by a dehydration reaction of a PVA film or a dehydrochlorination reaction of a PVC film to have polarization properties. However, the kinds of the polarizer 121 are not limited thereto.

The upper protective film 122 is disposed on the polarizer 121. For example, the upper protective film 122 may be made of one of polyethylene terephthalate, polyethersulfone, polycarbonate, polyimide, polypropylene, cyclo olefin polymer, cyclo olefin copolymer, and polymethylmethacrylate. Preferably, the upper protective film 122 may be a polyethylene terephthalate film. The polyethylene terephthalate film is cheap and easy to obtain and its properties such as a phase difference may be easily controlled.

The upper protective film 122 may be a retardation film, and may have the in-plane retardation value Rin and the thickness retardation value Rth of 10 nm or less (is between a positive non-zero value and a maximum of 10 nm). In this case, other colors are not recognized nor distorted depending on a viewing angle. Also, a difference in refractive index between the front viewing angle and another viewing angle may decrease, which may be recognized as low refraction. Thus, the viewing angle properties may be improved. Preferably, each of the in-plane retardation value Rin and the thickness retardation value Rth of the upper protective film 122 may between 1 nm to 3 nm.

Also, the thickness retardation value Rth of the upper protective film 122 may be equal to or smaller than the in-plane retardation value Rin. In this case, the color or transmittance is not affected by the viewing angle and thus is not changed. Also, the refractive index may not be changed, and, thus, the viewing angle properties may be improved. Therefore, the display quality may be improved.

In one example, the /4 retardation film 123 may be selectively disposed under the polarizer 121. The /4 retardation film 123 may be bonded to a lower part of the polarizer 121 by a second adhesive layer ADH2. The second adhesive layer ADH2 may be made of a pressure sensitive adhesive (PSA) but is not limited thereto.

When light reflected from a metal layer reaches the polarization film 120, the /4 retardation film 123 changes a light path so that the light does not pass through the polarization film 120. Therefore, it is possible to suppress a decrease in visibility by the reflected light.

The positive C plate 124 may be disposed under the /4 retardation film 123. The positive C plate 124 may be bonded to a lower part of the /4 retardation film 123 by a third adhesive layer ADH3. The third adhesive layer ADH3 may be made of a PSA, but is not limited thereto.

The positive C plate 124 may be fabricated by orienting a polymer film in a predetermined direction. Alternatively, the positive C plate 124 may be fabricated with a film in which a material such as liquid molecules, polyacrylate, polyester, cellulose ester, mesogen, styrenic polymer, styrenicfluoropolymer, and vinyl aromatic fluoropolymer is oriented. However, the present disclosure is not limited thereto.

The foldable display device 100 according to another exemplary aspect of the present disclosure includes the upper protective film 122 disposed on the polarizer 121. Thus, the viewing angle properties maybe further improved. Particularly, the in-plane retardation value Rin and the thickness retardation value Rth of the upper protective film 122 are set to 10 nm or less (is between a positive non-zero value and a maximum of 10 nm). Therefore, other colors are not recognized nor distorted depending on a viewing angle. Also, a difference in refractive index between the front viewing angle and another viewing angle decreases, which is recognized as low refraction. Thus, the viewing angle properties may be improved. Further, the thickness retardation value Rth of the upper protective film 122 is equal to or smaller than the in-plane retardation value Rin. Thus, the color or transmittance is not affected by the viewing angle and thus is not changed. Furthermore, the refractive index is not changed, and, thus, the viewing angle properties may be improved. Therefore, the display quality may be improved.

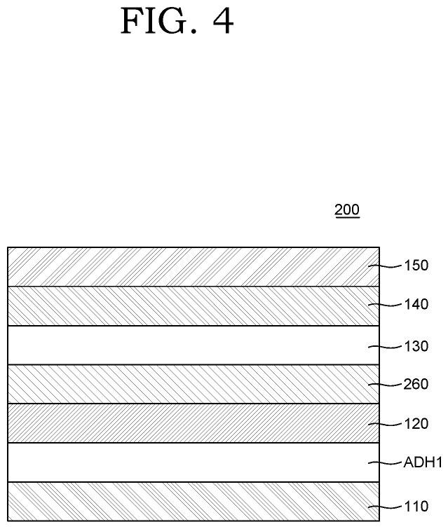

FIG. 4 is a schematic cross-sectional view of a foldable display device 200 according to an exemplary aspect of the present disclosure. The foldable display device 200 shown in FIG. 4 is substantially the same as the foldable display device 100 shown in FIG. 2 except that the example foldable display device 200 of FIG. 4 has a thin cover glass 260. Therefore, description of components of the display device 200 of FIG. 4 that are the same as those of the foldable display device 100 of FIG. 2 will not be further described for sake of brevity.

Referring to FIG. 4, the thin cover glass 260 is disposed between the polarization film 120 and the adhesive member 130. The thin cover glass 260 protects the display panel 110 so as not to be damaged by external impacts or degraded by moisture, oxygen and foreign matters from the outside.

The thin cover glass 260 may have a thickness of, for example, 0.1 mm or less, 50 m to 0.1 mm, or 70 m to 90 m. The thin cover glass 260 having such a thickness has excellent folding properties.

The thin cover glass 260 may be a chemically strengthened glass. The chemically strengthened glass is a glass which is strengthened by a chemical strengthening method. The chemical strengthening method is a process of enhancing the strength of the glass by an ion exchange method which replaces sodium ions included in the glass with ions having a greater ion radius than the sodium ions. As the ions having a greater ion radius than the sodium ions which configure the glass permeate, a compressive stress layer is formed on a surface of the glass to enhance the strength. For example, the chemically strengthened glass may be prepared as follows. Glass is immersed in a potassium salt solution such as potassium nitride and the sodium ions of the glass are substituted with potassium ions while heating at 200 C to 450 C equal to or lower than the glass transition temperature for a predetermined time. However, the present disclosure is not limited thereto.

If the chemically strengthened glass is used for the thin cover glass 260, it is possible to maintain high folding properties and improve impact resistance. Also, it is possible to improve scratch resistance and suppress a dent during folding or bending.

The thin cover glass 260 may be bonded onto the polarization film 120 by an adhesive. For example, the adhesive may be made of an optical clear adhesive for displays, such as a pressure sensitive adhesive, an optical clear adhesive, and an optical clear resin.

For example, the thin cover glass 260 may have a refractive index that is in the range of 1.51 to 1.53, an in-plane retardation value Rin of 1 nm or less, and a thickness retardation value Rth of 0 nm.

In the foldable display device 200 according to an exemplary aspect of the present disclosure, the polarization film 120 includes the upper protective film 122. The upper protective film 122 has the in-plane retardation value Rin and the thickness retardation value Rth of 10 nm or less (is between a positive non-zero value and a maximum of 10 nm), and the thickness retardation value Rth is equal to or smaller than the in-plane retardation value Rin. Also, the retardation film 140 is disposed on the polarization film 120. The retardation film 140 has the in-plane retardation value Rin and the thickness retardation value Rth of 10 nm or less (is between a positive non-zero value and a maximum of 10 nm), and the thickness retardation value Rth is equal to or smaller than the in-plane retardation value Rin. Further, the thin cover glass 260 is disposed between the polarization film 120 and the adhesive member 130. In this case, a black luminance is 0.000263 nit, which is smaller than a reference black luminance of 0.0005 nit. Thus, the HDR properties and the viewing angle properties may be improved. In the present specification, the black luminance is based on a black luminance for displaying an image signal black pattern for HDR 1.1 certification.

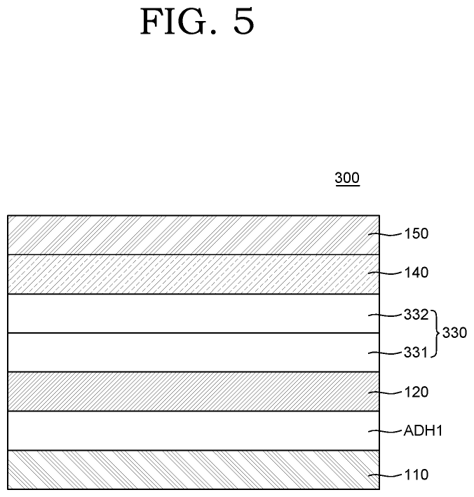

FIG. 5 is a schematic cross-sectional view of a foldable display device according to an exemplary aspect of the present disclosure. A foldable display device 300 according to an exemplary aspect of the present disclosure is substantially the same as the foldable display device 100 shown in FIG. 2 except that an adhesive member 330 of the example foldable device 300 of FIG. 5 includes a first adhesive member 331 and a second adhesive member 332. Description of components of the display device 300 of FIG. 5 that are the same as those of the foldable display device 100 of FIG. 2 will not be further described for sake of brevity.

Referring to FIG. 5, the first adhesive member 331 is disposed on the polarization film 120. For example, the first adhesive member 331 may adhere onto the polarization film 120. The first adhesive member 331 is a transparent adhesive member, and may be made of an optical clear adhesive, a pressure sensitive adhesive, an optical clear resin, and the like, but is not limited thereto. For example, if the first adhesive member 331 is made of the optical clear adhesive, an additive may be added to control the adhesiveness. Further, an additive which generates a thermal, UV, optical, or chemical reaction may be mixed into the first adhesive member 331.

The second adhesive member 332 is disposed on the first adhesive member 331. For example, the second adhesive member 332 may adhere onto the first adhesive member 331. The second adhesive member 332 is a transparent adhesive member, and may be made of an optical clear adhesive, a pressure sensitive adhesive, an optical clear resin, and the like, but is not limited thereto. For example, if the second adhesive member 332 is made of the optical clear adhesive, an additive may be added to control the adhesiveness. For example, an additive which generates a thermal, UV, optical, or chemical reaction may be mixed into the second adhesive member 332.

Here, the second adhesive member 332 may have a greater storage modulus than the first adhesive member 331. The second adhesive member 332 having a greater storage modulus than the first adhesive member 331 is disposed on the first adhesive member 331. In this case, the dent resistance properties, folding properties, and reliability of the foldable display device may be improved compared to a structure in which an adhesive member having a high storage modulus is disposed under the first adhesive member 331. Also, the flexibility may be enhanced. Therefore, it is possible to easily implement flexible display devices such as a foldable display device and a rollable display device. Preferably, the first adhesive member 331 may have a storage modulus of 10³ Pa to 10⁵ Pa, and the second adhesive member 332 may have a storage modulus of 10⁴ Pa to 10⁶ Pa.

Meanwhile, the second adhesive member 332 may have a greater refractive index than the first adhesive member 331. In this case, the second adhesive member 332 having a greater refractive index than the first adhesive member 331 is disposed on the first adhesive member 331. Thus, the micro-cavity effect is increased. Therefore, the HDR properties may be improved. Preferably, the first adhesive member 331 may have a refractive index of 1.43 to 1.49, and the second adhesive member 332 may have a refractive index of 1.51 to 1.55. In the foldable display device 300 according to an exemplary aspect of the present disclosure, the adhesive member 330 is composed of the first adhesive member 331 and the second adhesive member 332. Also, the second adhesive member 332 having a greater storage modulus than the first adhesive member 331 is disposed on the first adhesive member 331. Thus, the dent resistance properties, folding properties, and reliability may be improved. Therefore, it is possible to implement various flexible foldable display devices such as a foldable display device and a rollable display device. Further, the second adhesive member 332 having a greater refractive index than the first adhesive member 331 is disposed on the first adhesive member 331 to match the refractive indexes. Thus, the micro-cavity effect is increased. Therefore, the HDR properties may be improved.

Hereinafter, the effects of the present disclosure will be described in more detail with reference to several exemplary aspects. However, the following Exemplary Embodiments are set forth to illustrate the present disclosure, but the scope of the present disclosure is not limited thereto.

### Exemplary Aspect 1

In this exemplary aspect, a structure having a polarization film including an upper protective film, a retardation film bonded onto the polarization film by an adhesive member, and a hard coating layer on the retardation film was prepared. The upper protective film and the retardation film were formed to have a refractive index of 1.48, and each of the in-plane retardation value Rin and the thickness retardation value Rth thereof was set to 3 nm. Also, the adhesive member was formed to have a refractive index of 1.48.

### Exemplary Aspect 2

In this exemplary aspect, a structure was prepared in the same manner as in Exemplary Aspect 1 except a thin cover glass disposed between a polarization film and an adhesive member. The thin cover glass was formed to have a refractive index of 1.51, and the in-plane retardation value Rin thereof was set to 1 nm and the thickness retardation value Rth thereof was set to 0 nm.

### Exemplary Aspect 3

In this exemplary aspect, a structure was prepared in the same manner as in Exemplary Aspect 1 except an adhesive member composed of a first adhesive member and a second adhesive member. The first adhesive member was formed to have a refractive index of 1.45, and the second adhesive member was formed to have a refractive index of 1.51.

### Comparative Aspect 1

In this aspect, a structure was prepared in the same manner as in Exemplary Aspect 1 except that transparent polyimide was disposed on a polarization film, instead of the retardation film of Exemplary Aspect 1. The adhesive member was formed to have a refractive index of 1.47. Also, the transparent polyimide was formed to have a refractive index of 1.65, and the in-plane retardation value Rin thereof was set to 70 nm and the thickness retardation value Rth thereof was set to 6000 nm.

Black luminances of the above-described exemplary aspects respective structures prepared as described above were measured. Specifically, black luminances for displaying an image signal black pattern (black checkerboard pattern) for HDR 1.1 certification were measured. A result of measurement is shown in Table 1 below.

TABLE 1

| | Com. | Ex. | Ex. | Ex. |
|---|---|---|---|---|
| | Embodi- | Embodi- | Embodi- | Embodi- |
| | ment 1 | ment 1 | ment 2 | ment 3 |
| Black luminance | 0.000725 | 0.0000636 | 0.000263 | 0.000164 |
| (nit) | | | | |

Referring to Table 1, the structure of Comparative Aspect 1 including the transparent polyimide disposed on the polarization film has a greater black luminance than a reference black luminance of 0.0005 for the HDR properties. Thus, the structure of Comparative Aspect 1 has poor HDR properties. However, in the structures of Exemplary Aspects 1, 2 and 3, each of the retardation film and the polarization film including the upper protective film are disposed, the in-plane retardation value Rin and the thickness retardation value Rth thereof are set to 10 nm or less, and the refractive indexes of the upper protective film and the retardation film are matched. These structures have a smaller black luminance than the reference black luminance of 0.0005 for the HDR properties. Thus, the structures of Exemplary Aspects 1, 2 and 3 have excellent HDR properties.

It may be seen from the above-described result that if the retardation film and the polarization film including the upper protective film are disposed and the refractive indexes of the upper protective film and the retardation film are matched, the HDR properties may be improved.

Also, puncture strengths of the respective structures of Exemplary Aspect 3 and Comparative Aspect 1 were measured. A result of measurement is shown in Table 2 below.

TABLE 2

| | Comparative | Exemplary |
|---|---|---|
| | Embodiment 1 | Embodiment 3 |
| Puncture strength (kgf) | 8 | 9.2 |

Referring to Table 2, it may be seen that the structure of Exemplary Aspect 3 including the two adhesive members has excellent Puncture strength compared to the structure of Comparative Aspect 1 including the single adhesive member.

It may be seen from the above-described result that if the adhesive member is composed of two adhesive members, the Puncture strength are greatly improved. Thus, it is possible to provide a display device with excellent durability.

The exemplary embodiments of the present disclosure may also be described as follows:

According to an aspect of the present disclosure, there is provided a foldable display device. The foldable display device includes a display panel including a folding area to be folded with respect to a folding axis and a non-folding area, a polarization film on the display panel, an adhesive member on the polarization film and a retardation film on the adhesive member, wherein each of an in-plane retardation value Rin and a thickness retardation value Rth of the retardation film is 10 nm or less.

The thickness retardation value Rth of the retardation film may be equal to or smaller than the in-plane retardation value Rin.

The polarization film may be having a greater refractive index than the adhesive member, and the adhesive member may be having a greater refractive index than the retardation film.

The adhesive member may be having a storage modulus of 104 Pa to 106 Pa.

The adhesive member may be having are fractive index of 1.48 to 1.55.

The retardation film may be having are fractive index of 1.38 to 1.58.

Each of the in-plane retardation value and the thickness retardation value of the retardation film may be from 1 nm to 3 nm.

The polarization film may include a polarizer and an upper protective film on the polarizer, and each of an in-plane retardation value and a thickness retardation value of the upper protective film may be 10 nm or less, and the thickness retardation value of the upper protective film may be equal to or smaller than the in-plane retardation value.

The foldable display device may include a thin cover glass may be between the polarization film and the adhesive member.

The thin cover glass may be having a refractive index of 1.51 to 1.53.

An in-plane retardation value of the thin cover glass may be 1 nm, and a thickness retardation value of the thin cover glass may be 0 nm.

The adhesive member may include a first adhesive member on the polarization film and a second adhesive member on the first adhesive member, and the second adhesive member may be having a greater storage modulus than the first adhesive member.

The storage modulus of the first adhesive member may be 10³ Pa to 10⁵ Pa, and the storage modulus of the second adhesive member may be 10⁴ Pa to 10⁶ Pa.

The second adhesive member may be having a greater refractive index than the first adhesive member.

The refractive index of the first adhesive member may be 1.43 to 1.49, and the refractive index of the second adhesive member may be 1.51 to 1.55.

Features, structures, effects and the like described in the above-described examples of the present disclosure are included in at least one example of the present disclosure but are not necessarily limited to only one example. Furthermore, features, structures, effects and the like illustrated in at least one example of the present disclosure may be combined or modified with respect to other examples by one of ordinary skill in the art to which the present disclosure belongs. Accordingly, contents related to such combinations and modifications should be interpreted as being included in the scope of the present disclosure.

The present disclosure described above is not limited to the above-described embodiments and the accompanying drawings, and it will be apparent to one of ordinary skill in the technical field to which this disclosure pertains that various substitutions, modifications and changes are possible within the scope not departing from the technical matters of the present disclosure. Therefore, the scope of the present disclosure is indicated by the following claims, and all changes or modifications derived from the meaning and scope of the claims and their equivalent concepts should be construed as being included in the scope of the present disclosure.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A. B. or A and B. and can additionally include items not listed in the set of A and B.

What is claimed is:

1. A foldable display device, comprising:
a display panel including a folding area to be folded with respect to a folding axis and a non-folding area;
a polarization film on the display panel;
an adhesive member on the polarization film; and
a retardation film on the adhesive member,
wherein each of an in-plane retardation value and a thickness retardation value of the retardation film is 10 nm or less.

2. The foldable display device according to claim 1, wherein the thickness retardation value of the retardation film is equal to or smaller than the in-plane retardation value.

3. The foldable display device according to claim 1, wherein the polarization film has a greater refractive index than the adhesive member, and the adhesive member has a greater refractive index than the retardation film.

4. The foldable display device according to claim 1, further comprising:
an adhesive layer bonding the polarization film to the display panel.

5. The foldable display device according to claim 1, further comprising:
a hard coating layer on the retardation film having a contact angle to provide anti-fingerprint function.

6. The foldable display device according to claim 1, further comprising:
a hard coating layer on the retardation film; and
an anti-fingerprint layer on the hard coating layer.

7. The foldable display device according to claim 1, wherein the polarization film includes:
a polarizer; and
an upper protective film on the polarizer,
wherein
each of an in-plane retardation value and a thickness retardation value of the upper protective film is 10 nm or less, and
the thickness retardation value of the upper protective film is equal to or smaller than the in-plane retardation value.

8. The foldable display device according to claim 8, wherein the polarization film further comprises:
a second retardation film under the polarizer; and
a C plate under the second retardation film.

9. The foldable display device according to claim 1, wherein the polarization film includes:
an upper protective film having a thickness retardation value that is equal to or smaller than the in-plane retardation value.

10. The foldable display device according to claim 1, further comprising:
a thin cover glass between the polarization film and the adhesive member.

11. The foldable display device according to claim 10, wherein the thin cover glass has a refractive index of 1.51 to 1.53.

12. The foldable display device according to claim 10, wherein an in-plane retardation value of the thin cover glass is greater than a thickness retardation value of the thin cover glass.

13. The foldable display device according to claim 1, wherein the adhesive member includes:
a first adhesive member on the polarization film; and
a second adhesive member on the first adhesive member,
wherein the second adhesive member has a greater storage modulus than the first adhesive member.

14. The foldable display device according to claim 13, wherein the second adhesive member has a greater refractive index than the first adhesive member.

15. The foldable display device according to claim 1, further comprising:
a chemically strengthened glass on the display panel.

16. A display device, comprising:
a foldable display panel;
a polarization film on the foldable display panel;
an adhesive member on the polarization film; and
a retardation film on the adhesive member having an in-plane retardation value and a thickness retardation value,
wherein the thickness retardation value is equal to or less than the in-plane retardation value.

17. The display device according to claim 16, wherein the polarization film has a greater refractive index than the adhesive member, and the adhesive member has a greater refractive index than the retardation film.

18. The display device according to claim 16, wherein the polarization film includes:
an upper protective film having a thickness retardation value that is equal to or smaller than the in-plane retardation value.

19. The device of claim 16, wherein the adhesive member includes:
a first adhesive member on the polarization film; and
a second adhesive member on the first adhesive member,
wherein the second adhesive member has a greater storage modulus than the first adhesive member.

20. The device of claim 16, wherein the polarization film has a greater refractive index than the adhesive member, and the adhesive member has a greater refractive index than the retardation film.
